(19) United States
(12) Patent Application Publication
(10) Pub. No.: US 2009/0102812 A1
(43) Pub. Date: Apr. 23, 2009

(54) WIRING BOARD AND TOUCH PANEL USING THE SAME

(76) Inventors: Shigeyuki Fujii, Fukui (JP); Akira Nakanishi, Fukui (JP); Yasuhiko Hayashi, Fukui (JP)

Correspondence Address: WENDEROTH, LIND & PONACK L.L.P., 1030 15th Street, N.W., Suite 400 East, Washington, DC, 20005-1503, US

(21) Appl. No.: 12/255,981

(22) Filed: Oct. 22, 2008

(30) Foreign Application Priority Data
Oct. 23, 2007 (JP) 2007-274977

(51) Int. Cl. G06F 3/045; H05K 1/00

(52) U.S. Cl. 345/174; 174/250

(57) ABSTRACT

A wiring board includes a base, plural wiring patterns provided on the base, and plural connection patterns which extend from the wiring patterns, respectively, and which reach an outer periphery of the base. The wiring patterns are provided at an inner side of the outer periphery of the base. This wiring board can be manufactured easily and inexpensively and can securely prevent the short circuit between the wiring patterns.

### TECHNICAL FIELD

The present invention relates to a touch panel used for operating various electronic devices.

### BACKGROUND OF THE INVENTION

Electronic devices, such as mobile phones or car navigation systems, have recently had sophisticated functions. Such an electronic device includes a display element, such as a liquid crystal display, and a light-transmittable touch panel attached to a front surface of the display element. A user visually recognizes, through this touch panel, characters and marks displayed on the display element at the back surface of this touch panel to make choice. The user has a finger or a dedicated pen press the touch panel to switch the functions of the device. This touch panel has been required to be inexpensive and reliably operate.

FIG. 3 is a top view of conventional touch panel 501. Cutout 1A is provided in the center of an upper end of base 1 having a film shape. Wiring patterns 2 made of metal, such as copper plated with gold, is provided on an upper surface of base 1. Wiring patterns 2 extend from the upper end of base 1 to a lower end of base 1. A cover sheet having a film shape is adhered onto the upper surface of base 1. The cover sheet has a length in a longitudinal direction slightly shorter than that of base 1 so that the cover sheet covers the entire upper surface of base 1 to constitute wiring board 3. The cover sheet covers wiring patterns 2 to expose only the upper and lower ends of wiring patterns 2.

Upper resistive layer 7 made of light-transmittable material, such as indium tin oxide, is formed on a lower surface of light-transmittable upper board 5. Lower resistive layer 8 is formed on an upper surface of light-transmittable lower board 6. Plural dot spacers made of insulating resin are provided on an upper surface of lower resistive layer 8 with predetermined intervals between the dot spacers. Upper electrodes are arranged provided at both ends of upper resistive layer 7. Lower electrodes are provided at both ends of lower resistive layer 8 arranged along a direction perpendicular to a direction along which the upper electrodes are arranged. The upper and lower electrodes are introduced to a middle part of a lower end of lower board and between the lower end of upper board 5 and the lower end of lower board 6.

Spacer 9 having a substantially frame shape is provided between an outer periphery of the lower surface of upper board 5 and an outer periphery of the lower surface of the lower board 6. Adhesives applied to lower and upper surfaces of spacer 9 adhere spacer 9 to the outer periphery of upper board 5 and the outer periphery of lower board 6 so that upper resistive layer 7 faces lower resistive layer 8 with a predetermined gap between layers 7 and 8.

The upper end of wiring board 3 is held between the lower end of upper board 5 and the lower end of lower board 6. Conductive adhesive, such as anisotropically-conductive adhesive, made of synthetic resin including conductive particles dispersed therein connects the upper ends of wiring patterns 2 of wiring board 3 to the upper electrode and the lower electrode, thus providing touch panel 501.

FIG. 4 is a top view of conventional wiring board 3 for illustrating a method for manufacturing wiring board 3. A copper foil is adhered onto an upper surface of base sheet 11 functioning as base 1. First, the copper foil is etched to remove unnecessary portions to form wiring patterns 2 and connection pattern 12 connected to the upper end thereof.

Then, a current is flown from the upper end of connection pattern 12 to perform an electrolytic plating to form metal layers made of nickel or gold on wiring patterns 2 and connection pattern 12. Then, base sheet 11 is punched out to separate connection pattern 12 from wiring patterns 2, thus providing wiring board 3.

Touch panel 501 is provided on the front surface of a display element such as a liquid crystal display element to be installed in an electronic device. The lower ends of wiring patterns 2 of wiring board 3 are electrically connected to an electronic circuit of the device by, for example, a connection connector or soldering.

An operation of touch panel 501 will be described below. When the upper surface of upper board 5 is pressed with a finger or a pen in accordance with a display of the display element, the pressed portion of upper board 5 deforms to cause the pressed portion of upper resistive layer 7 to contact lower resistive layer 8.

The electronic circuit applies a voltage to both ends of the upper electrode, i.e., upper resistive layer 7, via wiring patterns 2 of wiring board 3. The pressed portion of lower resistive layer 8 contacts upper resistive layer 7. The electronic circuit detects the potential of the pressed portion of upper resistive layer 7 via lower resistive layer 8 and the lower electrodes, and detects, based on the detected potential, the position of the pressed portion in the direction along which the upper electrodes are arranged. The electronic circuit applies a voltage to both ends of the lower electrode, i.e., lower resistive layer 8, via wiring patterns 2 of wiring board 3. The electronic circuit detects the potential of the pressed portion of lower resistive layer 8 via upper resistive layer 7 and the upper electrode, and detects, based on the detected potential, the position of the pressed portion in the direction along which the lower electrodes are arranged. As described above, since the direction along which the upper electrodes are arranged is perpendicular to the direction along which the lower electrodes are arranged, the electronic circuit can detect the positions of continuous portions of upper board 5 which are pressed. The electronic circuit switches various functions of the electronic device based on the detected positions.

For example, while plural menus displayed on the display element, a portion of the upper surface of upper board 5 on a desired menu is pressed. The electronic circuit detects the pressed portion via wiring patterns 2 of wiring board 3, and operates according to the desired menu.

As touch panels 501 becomes inexpensive and has a smaller size, the intervals between wiring patterns 2 become narrower. When base sheet 11 is cut to separate wiring pattern 2 from connection pattern 12 to manufacture wiring board 3, fine thin metal burrs and scissile of wiring pattern 2 may be produced. The metal burrs and scissile may be attached to the lower end of wiring pattern 2 and short-circuit between wiring patterns 2. The metal burrs may be attached to the upper end of wiring board 3 between upper board 5 and the lower end of lower board 6, and short-circuit between the upper ends of wiring patterns 2 and the upper and lower electrodes or between the upper electrodes and the lower electrode, thereby preventing electrical connection or insulation from being stable.

In order to avoid this problem, after base sheet 11 is subjected to the punching processing, metal burrs or scraps are removed by, for example, brushing to avoid the short circuit. Then, wiring board 3 and touch panel 501 are manufactured. However, this method requires a time to manufacture wiring board 3 and touch panel 501.

### SUMMARY OF THE INVENTION

A wiring board includes a base, plural wiring patterns provided on the base, and plural connection patterns which extend from the wiring patterns, respectively, and which reach an outer periphery of the base. The wiring patterns are provided at an inner side of the outer periphery of the base.

This wiring board can be manufactured easily and inexpensively and can securely prevent the short circuit between the wiring patterns.

### BRIEF DESCRIPTION OF THE DRAWINGS

FIG. 1 is a top view of a touch panel according to an exemplary embodiment of the present invention.

FIG. 2A is a partial top view of a wiring board according to the embodiment for illustrating a method of manufacturing the wiring board.

FIG. 2B is a plan view of the wiring board according to the embodiment for illustrating the method of manufacturing the wiring board.

FIG. 2C is a cross-sectional view of the wiring board according to the embodiment for illustrating the method of manufacturing the wiring board.

FIG. 3 is a top view of a conventional touch panel.

FIG. 4 is a partial top view of a conventional wiring board for illustrating a method of manufacturing the conventional wiring board.

### DETAILED DESCRIPTION OF THE PREFERRED EMBODIMENT

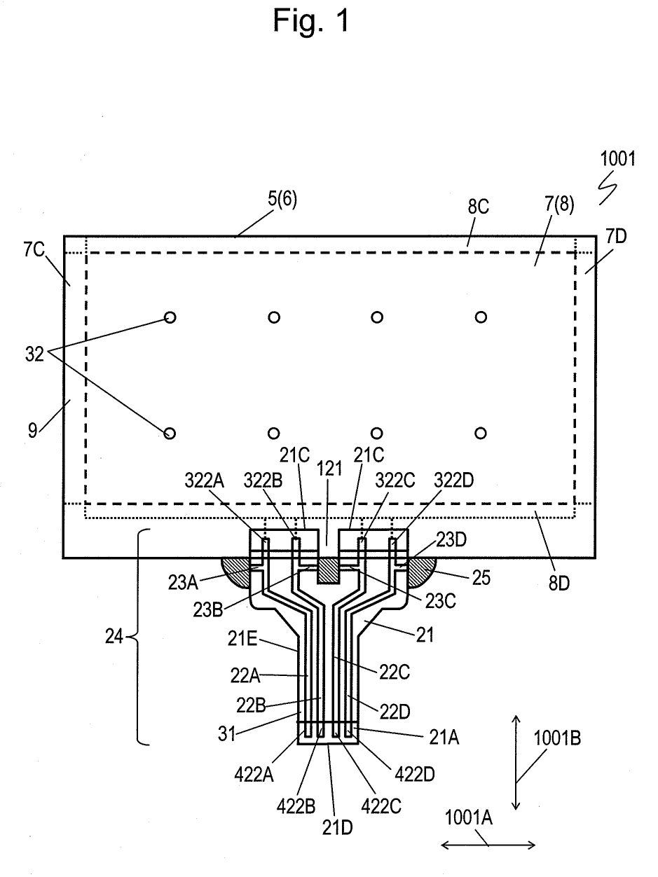

FIG. 1 is a top view of touch panel 1001 according to an exemplary embodiment of the present invention. Base 21 is made of insulating resin, such as polyimide or polyethylene terephthalate, and has a film shape. Cutout 121 is provided in a center of upper end 21C of base 21. Wiring patterns 22A to 22D made of conductive material are provided on upper surface 21A of base 21. Wiring patterns 22A to 22D have upper ends 322A to 322D, respectively, and have lower ends 422A to 422D, respectively. Wiring patterns 22A to 22D are located at an inner side of outer periphery 21E and away from outer periphery 21E. In particular, upper ends 322A to 322D of wiring patterns 22A to 22D are located at an inner side of upper end 21C, i.e., outer periphery 21E, of base 21. Lower ends 422A to 422D of wiring patterns 22A to 22D are located at an inner side of lower end 21D, i.e., outer periphery 21E, of base 21. Connection pattern 23A to 23D made of conductive material extend from portions between upper ends 322A to 322D and lower ends 422A to 422D of wiring patterns 22A to 22D, respectively, and reach outer periphery 21E of base 21. Connection patterns 23B and 23C extend to cutout 121. Connection patterns 23A and 23B extending from wiring patterns 22A and 22B adjacent to each other extend in directions opposite to each other and extend to ends of base 21 different from each other, respectively. Connection patterns 23C and 23D extending from wiring patterns 22C and 22D adjacent to each other extend in directions different from each other and extend to ends of base 21 different to each other.

Cover sheet 31 having a film shape is adhered onto upper surface 21A of base 21. Cover sheet 31 has a length in a longitudinal direction slightly shorter than that of base 21. Cover sheet 31 covers upper surface 21A of base 21, wiring patterns 22A to 22D, and connection patterns 23A to 23D to expose upper ends 322A to 322D and lower ends 422A to 422D of wiring patterns 22A to 22D. Specifically, cover sheet 31 exposes only upper ends 322A to 322D and lower ends 422A to 422D out of wiring patterns 22A to 22D and connection patterns 23A to 23D.

Upper board 5 has a film shape and is made of light-transmittable resin, such as polyethylene terephthalate, polycarbonate, or polyethersulfone. Lower board 6 is made of light-transmittable material, such as glass, acryl, or polycarbonate. Upper resistive layer 7 made of light-transmittable resistive material, such as indium tin oxide or tin oxide, is formed on a lower surface of upper board 5 by, for example, sputtering. Lower resistive layer 8 made of light-transmittable resistive material, such as indium tin oxide or tin oxide, is formed on an upper surface of lower board 6 by, for example, sputtering.

Dot spacers 32 made of insulating resin, such as epoxy or silicone, are provided on the upper surface of lower resistive layer 8 and arranged with predetermined intervals. Upper electrodes 7C and 7D made of conductive material, such as silver or carbon, are provided at both ends of upper resistive layer 7 arranged in direction 1001A. Lower electrodes 8C and 8D made of conductive material, such as silver or carbon, are provided at both ends arranged in direction 1001B perpendicular to direction 1001A of lower resistive layer 8. Upper electrodes 7C and 7D and lower electrodes 8C and 8D are drawn to middle portions of the lower ends of upper board 5 and the lower ends of lower board 6.

Spacer 9 is made of insulating resin, such as polyester or epoxy, and has a frame shape. Spacer 9 is provided between an outer periphery of the lower surface of upper board 5 and an outer periphery of the upper surface of lower board 6. Spacer 9 is adhered to the outer periphery of upper board 5 and the outer periphery of lower board 6 with adhesive, such as acryl or rubber, to allow upper resistive layer 7 to face lower resistive layer 8 with a predetermined gap between layers 7 and 8.

Upper end 21C of wiring board 24 is sandwiched between the lower end of upper board 5 and the lower end of lower board 6. Conductive adhesive adheres upper ends 322A to 322D of wiring patterns 22A to 22D of wiring board 24 to upper electrodes 7C and 7D and lower electrodes 8C and 8D, respectively, to connect the ends to the electrodes. According to this embodiment, the conductive adhesive is anisotropically-conductive adhesive including synthetic resin, such as epoxy, acryl, polyester, and conductive particles dispersed in the synthetic resin. The conductive particles may be metal particles, such as nickel, or resin having surface plated with gold. The conductive adhesive may be other conductive adhesive, such as solder.

Adhesive 25 applied to the lower end of upper board 5, the lower end of lower board 6, the upper end of wiring board 24, and the interior of notch 121, adheres wiring board 24 to upper board 5 and lower board 6, thereby providing touch panel 1001. Adhesive 25 is made of silicone, chloroprene, urethane rubber, acryl, or mixture thereof.

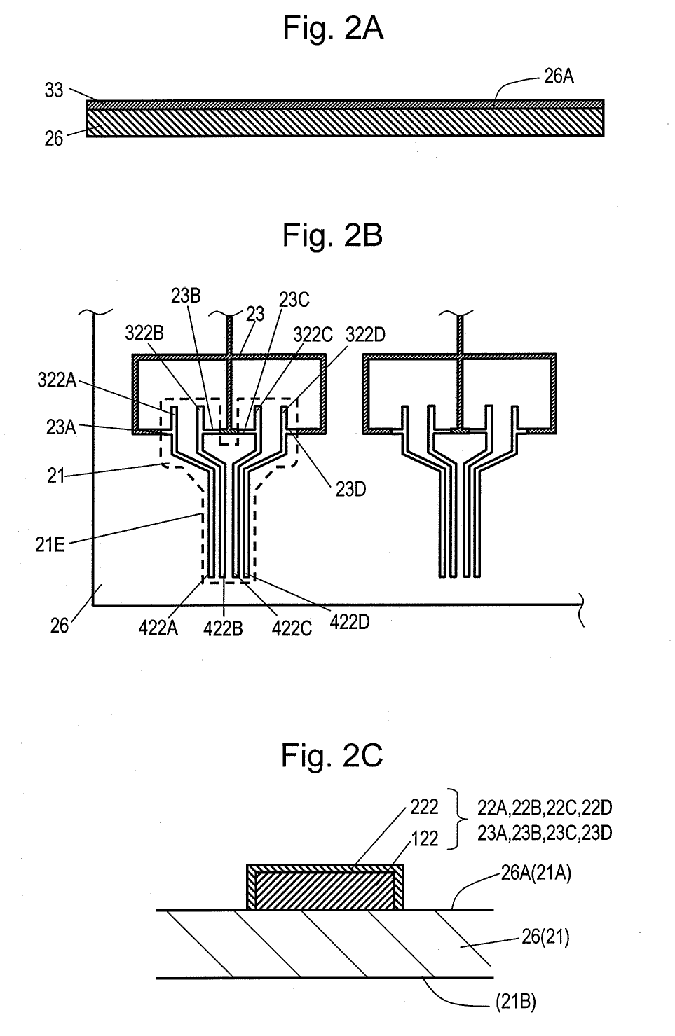

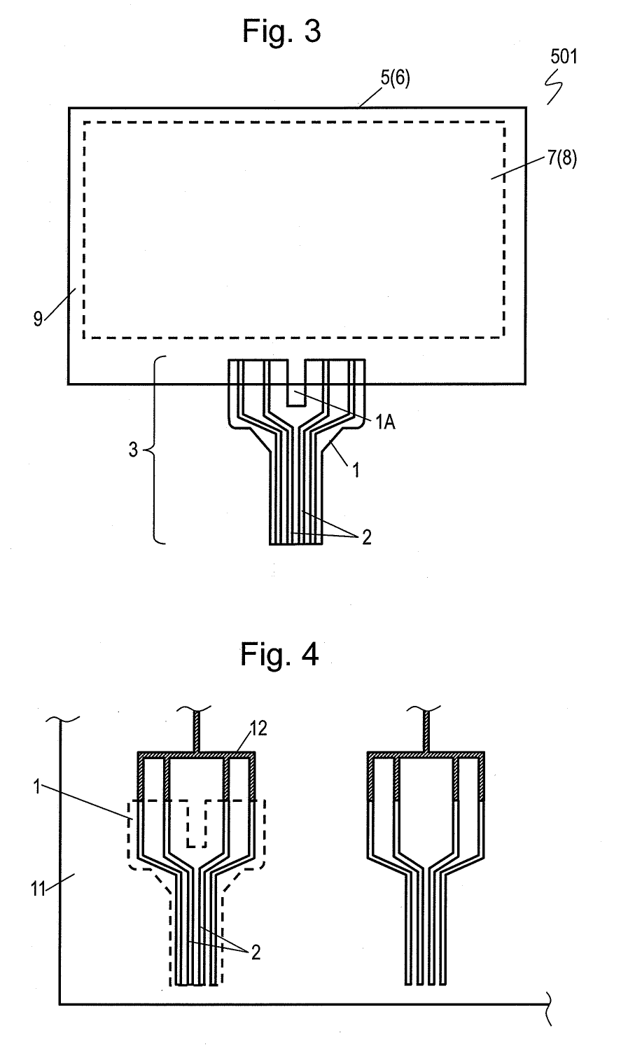

FIG. 2A is a cross sectional view of base sheet 26 for manufacturing wiring board 24. FIG. 2B is a partial top view of wiring board 24 for illustrating a method of manufacturing wiring board 24. FIG. 2C is a cross-sectional view of wiring patterns 22A to 22D and connection patterns 23A to 23D. As shown in FIG. 2A, base sheet 26 to be base 21 and metal foil 33, such as copper foil, provided on upper surface 26A of base sheet 26 are prepared. Metal foil 33 is etched to remove unnecessary portions of metal foil 33 to form conductive layer 122 shown in FIG. 2C. At this moment, conductive layer 122 to providing wiring patterns 22A to 22D and connection patterns 23A to 23D is connected to form conductive pattern 23.

Then, a current is flown to conductive layer 122 of conductive pattern 23 via connection patterns 23A to 23D to perform an electrolytic plating to form plated layer 222 made of nickel or gold on conductive layer 122, as shown in FIG. 2C, to form wiring patterns 22A to 22D and connection patterns 23A to 23D. Then, base sheet 26 and connection patterns 23A to 23D are cut by a punching process, thereby provide wiring board 24.

In other words, connection patterns 23A to 23D extend from portions of outer periphery 21E other than upper end 21C and lower end 21D of base 21 to form plated layer 222 on conductive layer 122. This arrangement locates upper ends 322A to 322D and lower ends 422A to 422D of wiring patterns 22A to 22D at an inner side of upper end 21C and lower end 21D, i.e., outer periphery 21E, of base 21 and away from upper end 21C and lower end 21D, i.e., outer periphery 21E, of base 21.

Wiring patterns 22A to 22D of wiring board 24 are not cut when base sheet 26 and connection patterns 23A to 23D are cut. Hence, wiring patterns 22A to 22D do not produce fine thin metal burrs or scraps. Hence, wiring patterns 22A to 22D are prevented from short-circuiting each other even if wiring patterns 22A to 22D are arranged with smaller intervals to have a narrow pitch.

Ends of connection patterns 23A to 23D which are cut extends to left and right ends of base 21 and cutout 121, that is, to portions outer periphery 21E other than upper end 21C and lower end 21D of base 21. As shown in FIG. 1, the ends of connection patterns 23A to 23D of touch panel 1001 are located at an outer side of upper board 5 and lower board 6. Even when metal burrs are produced at the ends of connection patterns 23A to 23D, the metal burrs are prevented from being attached to upper ends 322A to 322D of wiring patterns 22A to 22D between the lower end of upper board 5 and the lower end of lower board 6. Thus, touch panel 1001 can be manufactured inexpensively and easily without a process, such as brushing, for removing metal burrs and scraps.

Adhesive 25 is applied onto the lower end of upper board 5, the lower end of lower board 6, upper end 21C of base 21 (wiring board 24), and cutout 121. The ends of connection patterns 23A to 23D are covered by adhesive agent 25. Thus, even when metal burrs are produced at the ends of connection patterns 23A to 23D, adhesive 25 prevents the metal burrs from moving and projecting to the outer side of the adhesive. This structure prevents the short-circuiting, and allows the lower end of upper board 5 and the lower end of lower board 6 to be adhered to wiring board 24 securely.

Touch panel 1001 is provided in front of a front surface of a display element, such as a liquid crystal display to be installed in an electronic device. Lower ends 422A to 422D of wiring patterns 22A to 22D of wiring board 24 are electrically connected to an electronic circuit of the device by a connection connector or soldering for example.

An operation of touch panel 1001 will be described below. When the upper surface of upper board 5 is pressed by, for example, a finger or a pen in accordance with a display on the display element, the pressed portion of upper board 5 deforms to allow the pressed portion of upper resistive layer 7 to contact lower resistive layer 8.

The electronic circuit applies a voltage to upper electrodes 7C and 7D, i.e., both ends of upper resistive layer 7, via wiring patterns 22A to 22D of wiring board 24. The pressed portion of lower resistive layer 8 contacts upper resistive layer 7. The electronic circuit detects the potential of the pressed portion of upper resistive layer 7 via lower resistive layer 8 and lower electrodes 8C and 8D to detect, based on this potential, the position of the pressed portion in direction 1001A. The electronic circuit applies a voltage to lower electrodes 8C and 8D, i.e., both ends of lower resistive layer 8, via wiring patterns 22A to 22D of wiring board 24. The electronic circuit detects the potential of the pressed portion of lower resistive layer 8 via upper resistive layer 7 and upper electrodes 7C and 7D to detect, based on this potential, the position of the pressed portion in direction 1001B. As described above, direction 1001A along which upper electrodes 7C and 7D are arranged is perpendicular to direction 1001B along which lower electrodes 8C and 8D are arranged. Thus, the electronic circuit can detect the position of continuous portions of upper board 5 which are pressed. Based on the detected position, the electronic circuit switches various functions of the electronic device.

While plural menus are displayed on the display element, a portion of the upper surface of upper board 5 on a desired menu is pressed. The electronic circuit detects the pressed portion via wiring patterns 22A to 22D of wiring board 24, and operates according to the desired menu.

As described above, touch panel 1001 does not have the short-circuiting due to the fine thin metal burrs or scissile that may be produced during the manufacturing of wiring board 24 and that may be located between wiring patterns 22A to 22D, upper electrodes 7C and 7D, and lower electrodes 8C and 8D. Therefore, touch panel 1001 can reliably operate by the pressing so that resistive layers 7 and 8 are stably connected electrically to each other and stably disconnected electrically from each other.

In wiring board 24 according to the embodiment, four wiring patterns 22A to 22D and four connection patterns 23A to 23D are formed on upper surface 21A of base 21. Some wiring patterns of wiring patterns may be formed on upper surface 21A of base 21 while other wiring patterns of the wiring patterns may be formed on lower surface 21B of base 21 opposite to upper surface 21A. Alternatively, wiring patterns may be formed on lower surface 21B of base 21 near upper end 21C of base 21, while the wiring pattern may be formed on upper surface 21 of base 21 near lower end 21D. In this case, base 21 has through-holes filled with conductive material, such as silver. These through-holes connect the wiring patterns formed on upper surface 21A to the wiring patterns formed on lower surface, respectively.

What is claimed is:

1. A wiring board comprising:
a base having an outer periphery;
a plurality of wiring patterns provided on the base at an inner side of the outer periphery of the base; and
a plurality of connection patterns extending from the plurality of wiring patterns, respectively, the plurality of connection pattern reaching the outer periphery of the base.

2. A touch panel comprising:
an upper board;
an upper resistive layer provided on the upper board;
a lower board;
a lower resistive layer provided on the lower board, the lower resistive layer facing the upper resistive layer with a predetermined gap between the upper resistive layer and the lower resistive layer;
a wiring board including
a base having an outer periphery
a plurality of wiring patterns provided on the base at an inner side of the outer periphery of the base, and
a plurality of connection patterns extending from the plurality of wiring patterns, respectively, the plurality of connection pattern reaching the outer periphery of the base; and
a plurality of electrodes connecting the plurality of the wiring patterns to the upper resistive layer and the lower resistive layer.
